(19) United States
(12) Patent Application Publication
(10) Pub. No.: US 2023/0029827 A1
(43) Pub. Date: Feb. 2, 2023

(54) INTEGRATED CIRCUIT SEMICONDUCTOR DEVICE

(71) Applicant: Samsung Electronics Co., Ltd., Suwon-si (KR)

(72) Inventors: Junmo Park, Seoul (KR); Yeonho Park, Seoul (KR); Eunsil Park, Hwaseong-si (KR); Jinseok Lee, Busan (KR); Wangseop Lim, Cheonan-si (KR); Kyubong Choi, Seoul (KR)

(73) Assignee: Samsung Electronics Co., Ltd., Suwon-si (KR)

(21) Appl. No.: 17/685,593

(22) Filed: Mar. 3, 2022

(30) Foreign Application Priority Data
Jul. 30, 2021 (KR) 10-2021-0100684

(51) Int. Cl. H01L 27/092; H01L 21/8238

(52) U.S. Cl. CPC H01L 27/092; H01L 21/823842; H01L 21/82385

(57) ABSTRACT

An integrated circuit semiconductor device includes a first region including first active fins extending in a first direction, and first transistors including first gate electrodes extending in a second direction, a second region in contact with the first region in the second direction, wherein the second region includes second active fins extending in the first direction, and second transistors including second gate electrodes extending in the second direction. The integrated circuit semiconductor device includes metal dams at a boundary of the first region and the second region to separate the first gate electrodes and the second gate electrodes in the second direction, wherein the metal dams, the first gate electrodes, and the second gate electrodes are electrically connected in the second direction.

### CROSS-REFERENCE TO RELATED APPLICATION

This application is based on and claims priority under 35 U.S.C. § 119 to Korean Patent Application No. 10-2021-0100684, filed on Jul. 30, 2021, in the Korean Intellectual Property Office, the disclosure of which is incorporated by reference herein in its entirety.

### BACKGROUND

The inventive concept relates to an integrated circuit semiconductor device, and more particularly, to an integrated circuit semiconductor device including three-dimensional transistors.

In relation to an integrated circuit semiconductor device, transistors have to be reliably formed on a substrate to meet the excellent performance demanded by consumers. However, as integrated circuit semiconductor devices are highly integrated, when an integrated circuit semiconductor device consists of three-dimensional transistors, that is, three-dimensional transistors rather than planar transistors, it is becoming difficult to reliably form three-dimensional transistors on a substrate.

### SUMMARY

The inventive concept provides an integrated circuit semiconductor device in which three-dimensional transistors are reliably formed.

According to an aspect of the inventive concept, there is provided an integrated circuit semiconductor device including: a first region including first active fins extending in a first direction and spaced apart from each other in a second direction perpendicular to the first direction, and first transistors including first gate electrodes extending in the second direction on the first active fins and spaced apart from each other in the first direction; and a second region arranged in contact with the first region in the second direction, wherein the second region includes second active fins extending in the first direction and spaced apart from each other in the second direction, and second transistors including second gate electrodes extending in the second direction on the second active fins and spaced apart from each other in the first direction.

The integrated circuit semiconductor device includes a plurality of metal dams positioned at a boundary of the first region and the second region to physically separate the first gate electrodes and the second gate electrodes in the second direction, wherein the metal dams, the first gate electrodes, and the second gate electrodes are electrically connected in the second direction.

According to another aspect of the inventive concept, there is provided an integrated circuit semiconductor device including: a first region including a first active fin extending in a first direction on the substrate, a first gate dielectric layer extending from a top surface of the first active fin onto a first isolation layer in a second direction perpendicular to the first direction, and a first gate electrode extending in the second direction on the first gate dielectric layer; and a second region arranged on the substrate in contact with the first region in the second direction, wherein the second region includes a second active fin extending in the first direction, a second gate dielectric layer extending from a top surface of the second active fin onto a second isolation layer in the second direction, and a second gate electrode extending in the second direction on the second gate dielectric layer.

The integrated circuit semiconductor device includes a metal dam positioned at a boundary of the first region and the second region to physically separate the first gate electrode and the second gate electrode in the second direction, wherein the metal dam, the first gate electrode, and the second gate electrode are electrically connected to each other.

According to another aspect of the inventive concept, there is provided an integrated circuit semiconductor device including: a first region including a first multi-bridge channel transistor including a first active fin protruding from a substrate and extending in a first direction, a first gate dielectric layer extending from a top surface of the first active fin onto a first isolation layer in a second direction perpendicular to the first direction, a plurality of first nano-sheets stacked apart from the first gate dielectric layer, a third gate dielectric layer surrounding the first nano-sheets, first and second barrier metal layers formed on the first gate dielectric layer, on an upper portion of the third gate dielectric layer, and between the first nano-sheets and extending in the second direction, and a first gate electrode formed on the second barrier metal layer; and a second region formed adjacent to the first region in the second direction, wherein the second region includes a second multi-bridge channel transistor including a second active fin protruding from the substrate and extending in the first direction, a second gate dielectric layer extending from a top surface of the second active fin onto a second isolation layer in the second direction, a plurality of second nano-sheets stacked apart from the second gate dielectric layer, a fourth gate dielectric layer surrounding the second nano-sheets, a third barrier metal layer formed on the second gate dielectric layer, on an upper portion of the fourth gate dielectric layer, and between the second nano-sheets and extending in the second direction, and a second gate electrode formed on the third barrier metal layer.

The integrated circuit semiconductor device includes a metal dam positioned at a boundary of the first region and the second region to physically separate the first gate electrode and the second gate electrode in the second direction, wherein the metal dam, the first gate electrode, and the second gate electrode are electrically connected to each other.

### BRIEF DESCRIPTION OF THE DRAWINGS

Embodiments of the inventive concept will be more clearly understood from the following detailed description taken in conjunction with the accompanying drawings in which:

FIG. 1 is a layout diagram of an integrated circuit semiconductor device according to an embodiment of the technical concept of the inventive concept;

FIG. 2 is a cross-sectional view taken along line II-II′ of FIG. 1;

FIG. 3 is a cross-sectional view taken along line of FIG. 1;

FIGS. 4 to 14 are cross-sectional views illustrating a method of manufacturing nano-sheet stacked structures and a metal dam pattern of the integrated circuit semiconductor device of FIG. 3;

FIGS. 15 to 22 are cross-sectional views illustrating a method of manufacturing barrier metal layers and gate electrodes of the integrated circuit semiconductor device of FIG. 3;

FIG. 23 is a block diagram illustrating a configuration of a semiconductor chip including an integrated circuit semiconductor device according to an embodiment of the inventive concept;

FIG. 24 is a block diagram illustrating a configuration of a semiconductor chip including an integrated circuit semiconductor device according to an embodiment of the inventive concept;

FIG. 25 is a block diagram illustrating a configuration of an electronic device including an integrated circuit semiconductor device according to an embodiment of the inventive concept; and

FIG. 26 is an equivalent circuit diagram of a static random-access memory (SRAM) cell according to an embodiment of the inventive concept.

### DETAILED DESCRIPTION OF THE EMBODIMENTS

Hereinafter, preferred embodiments of the inventive concept will be described in detail with reference to the accompanying drawings. Each of the following embodiments of the inventive concept may be implemented in a device, or two or more of the following embodiments may be combined to be implemented in a device. Therefore, the technical idea of the inventive concept is not limited to the embodiments.

In the present specification, each singular form of constituent elements may represent any one of a plurality of corresponding elements included in the embodiments unless the context clearly indicates otherwise. For example, singular forms of elements in this disclosure may imply that corresponding embodiments may include plural corresponding elements unless the context indicates otherwise. In the present specification, drawings are exaggerated in order to more clearly describe the inventive concept.

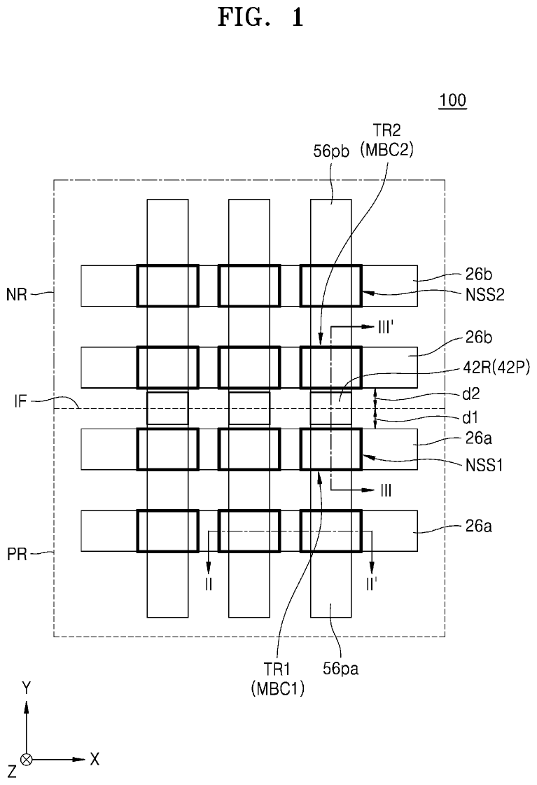

FIG. 1 is a layout diagram of an integrated circuit semiconductor device according to an embodiment of the technical concept of the inventive concept.

For example, the integrated circuit semiconductor device 100 may include a first region PR on a substrate (not shown), a second region NR, and a plurality of metal dam regions 42R positioned near the boundary line IF between the first region PR and the second region NR. For example, the metal dam regions 42R may be metal dams 42R formed of metal patterns. For example, each of the metal dams 42R may overlap the boundary line between the first region PR and the second region NR. For example, each of the metal dams 42R may be positioned at a boundary between the first region PR and the second region NR. The first region PR and the second region NR may be regions in which three-dimensional transistors are to be formed. For example, the three-dimensional transistors may have a structure in which multiple transistors are stacked in a vertical direction Z in addition to horizontally and two-dimensionally arranged transistors.

The first region PR is a region in which a first transistor TR1, e.g., a P-type transistor, is to be formed. The first transistor TR1 may be a MOS transistor. The first region PR is a region in which a P-type multi-bridge channel transistor MBC1 is to be formed.

The second region NR may be a region in which a second transistor TR2, e.g., an N-type transistor, is to be formed. The second transistor TR2 may be a MOS transistor. The second region NR is a region in which an N-type multi-bridge channel transistor MBC2 is to be formed.

The metal dam regions 42R may serve as dams (or barriers) to form the gate electrodes 56pa and 56pb of the first region PR and the second region NR without damage.

In FIG. 1, a first direction (X direction) may be a channel length direction, and a second direction (Y direction) may be a channel width direction. Hereinafter, the layout of the integrated circuit semiconductor device 100 will be described in more detail, and the technical spirit of the inventive concept is not limited to the layout of FIG. 1.

The first region PR may include a plurality of first active fins 26a extending in the first direction (X direction) and spaced apart from each other in the second direction (Y direction). The first active fins 26a may provide an active region of a first transistor TR1. The first region PR may include a plurality of first gate electrodes 56pa extending in the second direction (Y direction) perpendicular to the first direction (X direction) and spaced apart from each other in the first direction (X direction).

In the first region PR, the first gate electrodes 56pa may be positioned on the first active fins 26a. In the first region PR, a first nano-sheet stacked structure NSS1 may be positioned at an overlapping portion where a first active fin 26a and a first gate electrode 56pa crosses each other. For example, the first active fins 26a and the first gate electrodes 56pa may vertically overlap each other. For example, each of the first nano-sheet stacked structures NSS1 may be formed between a first active fin 26a and a first gate electrode 56pa vertically overlapping each other and may also vertically overlap the first active fin 26a and the first gate electrode 56pa. The structure of the first nano-sheet stacked structure NSS1 will be described in detail later.

The second region NR may be arranged in contact with the first region PR in the second direction (Y direction). The second region NR may include a plurality of second active fins 26b extending in the first direction (X direction) and spaced apart from each other in the second direction (Y direction). The second active fins 26b may provide an active region of a second transistor TR2. The second region NR may include a plurality of second gate electrodes 56pb extending in the second direction (Y direction) perpendicular to the first direction (X direction) and spaced apart from each other in the first direction (X direction).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

In the second region NR, the second gate electrodes 56pb may be arranged on the second active fins 26b. In the second region NR, a second nano-sheet stacked structure NSS2 may be positioned at an overlapping portion where a second active fin 26b and a second gate electrode 56pb crosses each other. For example, the second active fins 26b and the second gate electrodes 56pb may vertically overlap each other. For example, each of the second nano-sheet stacked structures NSS2 may be formed between a second active fin 26b and a second gate electrode 56pb vertically overlapping each other and may also vertically overlap the second active fin 26b and the second gate electrode 56pb. The structure of the second nano-sheet stacked structure NSS2 will be described in detail later.

As described above, the metal dam regions 42R may be dams (or barriers) to form the gate electrodes 56pa and 56pb of the first region PR and the second region NR without damage. The metal dam regions 42R are arranged such that the first gate electrodes 56pa and the second gate electrodes 56pb are physically separated adjacent to or at the boundary line IF of the first region PR and the second region NR in the second direction (Y direction). For example, metal dams may be formed between the first gate electrodes 56pa and the second gate electrodes 5pb in the second direction Y. The metal dam regions 42R may be arranged to be spaced apart from each other in the first direction (X direction).

The metal dam regions 42R may be positioned at the same distance from the first active fins 26a and the second active fins 26b in the second direction. For example, the center line of the metal dam regions 42R extending in the first direction X, e.g., the boundary line IF of the first region PR and the second region NR, may be positioned at a first distance d1 and a second distance d2 from the closest one of the first active fins 26a and the closest one of the second active fins 26b in the second direction, respectively. In some embodiments, the first distance d1 may be the same as the second distance d2. If necessary, the first distance d1 and the second distance d2 may be arranged differently.

The metal dam regions 42R may be formed of metal dam patterns 42P. The metal dam regions 42R may be electrically connected to the first gate electrodes 56pa and the second gate electrodes 56pb in the second direction (Y direction). The first gate electrodes 56pa and the second gate electrodes 56pb are electrically connected to each other in the second direction (Y direction). The first gate electrodes 56pa and the second gate electrodes 56pb may be electrically and physically connected in the second direction (Y direction) through the metal dam regions 42R. The structure of the metal dam regions 42R will be described in detail later. For example, widths of the first gate electrodes 56pa, the second gate electrodes 56pb and the dam patterns 42R in the second direction may be the same, and top surfaces of the first gate electrodes 56pa, the second gate electrodes 56pb and the dam patterns 42R may be at the same vertical level at the boundary between the first region PR and the second region NR.

As used herein, components described as being “electrically connected” are configured such that an electrical signal can be transferred from one component to the other (although such electrical signal may be attenuated in strength as it transferred and may be selectively transferred).

The integrated circuit semiconductor device 100 configured as described above includes the metal dam regions 42R so that the first and second gate electrodes 56pa and 56pb may be formed without damage. In addition, the integrated circuit semiconductor device 100 may precisely arrange the metal dam regions 42R in the vicinity of the boundary line IF of the first region PR and the second region NR. For example, each of the metal dams 42R may be positioned at the same distance from a closest first nano-sheets-stacked structure NSS1 of the first region PR and a closet second nano-sheets-stacked structure NSS2 of the second region NR in the second direction.

Accordingly, the integrated circuit semiconductor device 100 may suppress the metal gate boundary effect in which the threshold voltages of the first transistors TR1 of the first region PR and the threshold voltages of the second transistors TR2 of the second region NR deviate from a design value. As a result, the integrated circuit semiconductor device 100 may reliably configure three-dimensional transistors, for example, the multi-bridge channel transistors MBC1 and MBC2.

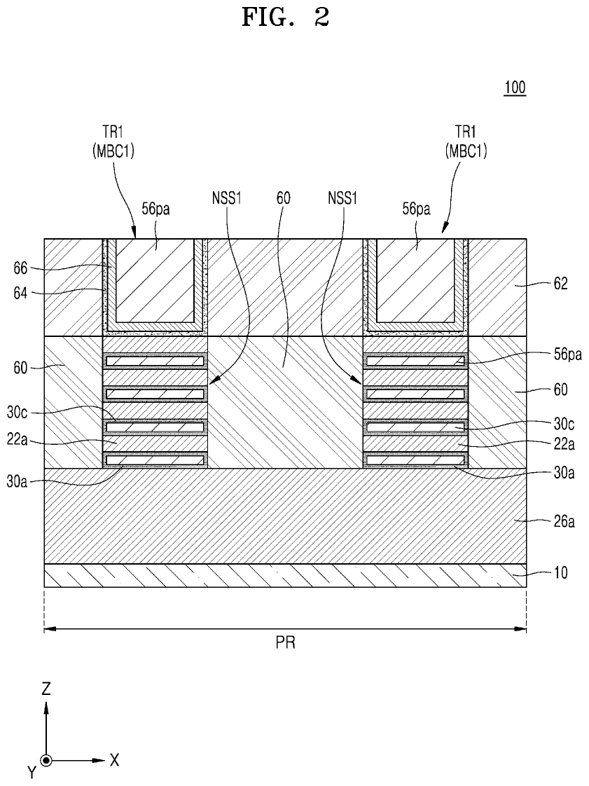

FIG. 2 is a cross-sectional view taken along line II-II′ of FIG. 1.

In the description with respect to FIG. 2, each component is mostly described in the singular rather than the plural, except for special cases. The integrated circuit semiconductor device 100 may include a substrate 10 having a first region PR. As described above, the first region PR is a region in which a first transistor TR1, for example, a P-type multi-bridge channel transistor MBC1, is to be formed.

A first active fin 26a may be formed on the substrate 10. A first nano-sheet stacked structure NSS1 is formed on the first active fin 26a. The first nano-sheet stacked structure NSS1 may include a plurality of first nano-sheets 22a spaced apart from each other in a third direction (Z direction).

A first gate dielectric layer 30a is formed on the first active fin 26a. A third gate dielectric layer 30c is formed on upper and lower surfaces of the first nano-sheets 22a. A fifth gate dielectric layer 64 is formed on the uppermost first nano-sheets 22a. The fifth gate dielectric layer 64 may be formed of the same material as the third gate dielectric layer 30c.

A first gate electrode 56pa is formed on the first gate dielectric layer 30a, between the first nano-sheets 22a, and on the uppermost first nano-sheet 22a. A fourth barrier metal layer 66 may be formed on an upper portion of the uppermost first nano-sheet 22a and on both sidewalls of the first gate electrode 56pa. The fourth barrier metal layer 66 may be formed of the same material as the first and second barrier metal layers to be described later.

Source and drain regions 60 may be formed on both sides of the lower portions of the first gate electrode 56pa and on both sides of the first nano-sheet stacked structure NSS1. An interlayer insulating layer 62 may be formed around the first gate electrode 56pa.

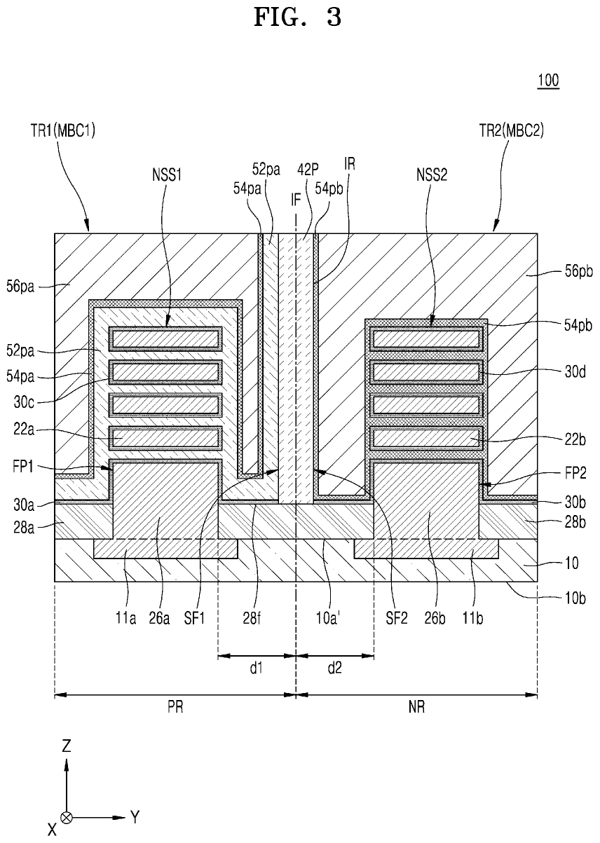

FIG. 3 is a cross-sectional view taken along line of FIG. 1.

In the description with respect to FIG. 3, each component is mostly described in the singular rather than the plural, except for special/certain cases. The integrated circuit semiconductor device 100 may include a substrate 10 having a first region PR and a second region NR. As described above, the first region PR is a region in which a first transistor TR1, for example, a P-type multi-bridge channel transistor MBC1, is to be formed. The second region NR is a region in which a second transistor TR2, for example, an N-type multi-bridge channel transistor MBC2, is to be formed.

The substrate 10 may include a surface 10a′ and a rear surface 10b. A first well region 11a, e.g., a P-type well region, is formed in the first region PR. A second well region 11b, e.g., an N-type well region, is formed in the second region NR. A first active fin 26a, for example, a P-type active fin, is formed in the first well region 11a.

A second active fin 26b, for example, an N-type active fin, is formed on the second well region 11b. A first isolation layer 28a is formed to surround the lower periphery of the first active fin 26a. A second isolation layer 28b is formed at the lower periphery of the second active fin 26b.

The first active fin 26a may include a first fin protrusion FP1 protruding from the surface 28f of the first isolation layer 28a. The second active fin 26b may include a second fin protrusion FP2 protruding from the surface 28f of the second isolation layer 28b. A first nano-sheet stacked structure NSS1 is formed on the first active fin 26a. The first nano-sheet stacked structure NSS1 may include a plurality of first nano-sheets 22a spaced apart from each other in a third direction (Z direction).

Although four of the first nano-sheets 22a are stacked in FIG. 3, more or fewer stacks may be used in certain embodiments. The number of stacks of the first nano-sheets 22a does not limit the inventive concept. The first nano-sheets 22a may include a silicon layer. For example, each of the first nano-sheets 22a may be a silicon layer.

A second nano-sheet stacked structure NSS2 is formed on the second active fin 26b. The second nano-sheet stacked structure NSS2 may include a plurality of second nano-sheets 22b arranged apart from each other in the third direction (Z direction). Although four of the second nano-sheets 22b are stacked in FIG. 3, more or fewer stacks may be used in certain embodiments. The number of stacked second nano-sheets 22b does not limit the inventive concept. The second nano-sheets 22b may include a silicon layer. For example, each of the second nano-sheets 22b may be a silicon layer.

A first gate dielectric layer 30a is formed in the first region PR. The first gate dielectric layer 30a is formed on the first active fin 26a. The first gate dielectric layer 30a is formed to extend from a top surface of the first active fin 26a in the second direction (Y direction) onto the first isolation layer 28a. A third gate dielectric layer 30c surrounding the first nano-sheets 22a is formed in the first region PR.

A second gate dielectric layer 30b is formed in the second region NR. The second gate dielectric layer 30b is formed on the second active fin 26b. The second gate dielectric layer 30b is formed to extend from a top surface of the second active fin 26b in the second direction (Y direction) onto the second isolation layer 28b. A fourth gate dielectric layer 30d surrounding the second nano-sheets 22b is formed in the second region NR.

In the first region PR, first and second barrier metal layers 52pa and 54pa and a first gate electrode 56pa may be formed on the first nano-sheet stacked structure NSS1. The first and second barrier metal layers 52pa and 54pa may be first and second threshold voltage control layers respectively.

The first barrier metal layer 52pa may be formed between the first gate dielectric layer 30a on the first active fin 26a and the lowermost first nano-sheet 22a, between the third gate dielectric layers 30c on the first nano-sheets 22a, and on the third gate dielectric layers 30c on the first nano-sheets 22a. For example, the first barrier metal layer 52pa may contact the first gate dielectric layer 30a and the third gate dielectric layers 30c. The second barrier metal layer 54pa may be formed on the first barrier metal layer 52pa. For example, the second barrier metal layer 54pa may contact the first barrier metal layer 52pa and the first gate electrode 56pa. The first barrier metal layer 52pa may be thicker than the second barrier metal layer 54pa. The first gate electrode 56pa may be formed on the second barrier metal layer 54pa on the first nano-sheet stacked structure NSS1.

A third barrier metal layer 54pb and a second gate electrode 56pb may be formed on the second nano-sheet stacked structure NSS2 in the second region NR. The third barrier metal layer 54pb may be a third threshold voltage control layer.

The third barrier metal layer 54pb may be formed between the second gate dielectric layer 30b on the second active fin 26b and the lowermost second nano-sheet 22b, between the fourth gate dielectric layers 30d on the second nano-sheets 22b, and on the fourth gate dielectric layers 30d on the second nano-sheets 22b. For example, the third barrier metal layer 54pb may contact the second gate dielectric layer 30b and the fourth gate dielectric layers 30d. The second gate electrode 56pb may be formed on the third barrier metal layer 54pb on the second nano-sheet stacked structure NSS2. For example, the second gate electrode 56pb may contact the third barrier metal layer 54pb. The first barrier metal layer 52pa and the second barrier metal layer 54pa in the first region may be thicker than the third barrier metal layer 54pb.

A metal dam pattern 42P is formed in the isolation region IR near the boundary line IF between the first region PR and the second region NR. The metal dam pattern 42P may be positioned at the same distance from the first active fins 26a and the second active fins 26b in the second direction.

For example, the center line of the metal dam pattern 42P, e.g., the boundary line IF of the first region PR and the second region NR, may be positioned at a first distance d1 and a second distance d2 from the first active fin 26a and the second active fin 26b in the second direction, respectively. In some embodiments, the first distance d1 may be the same as the second distance d2. If necessary, the first distance d1 and the second distance d2 may be different from each other in certain embodiments.

First and second barrier metal layers 52pa and 54pa may be formed on one sidewall SF1 of the metal dam pattern 42P, and a third barrier metal layer 54pb may be formed on another sidewall SF2 of the metal dam pattern 42P. The lower width (e.g., a width of a lower part of the metal dam pattern 42P) may be the same as the upper width (e.g., a width of an upper part) of the metal dam pattern 42P in the second direction. For example, the width of the metal dam pattern 42P in the second direction may be uniform throughout the metal dam pattern 42P. As described above, the metal dam pattern 42P and the first gate electrode 56pa and the second gate electrode 56pb are electrically connected to each other in the second direction (Y direction) on the metal dam pattern 42P.

The integrated circuit semiconductor device 100 as described above is provided with a metal dam pattern 42P, such that as will be described later, the first gate electrode 56pa and the second gate electrode 56pb may be formed without damage. Accordingly, the integrated circuit semiconductor device 100 may reliably configure the three-dimensional transistors TR1 and TR2, for example, the multi-bridge channel transistors MBC1 and MBC2.

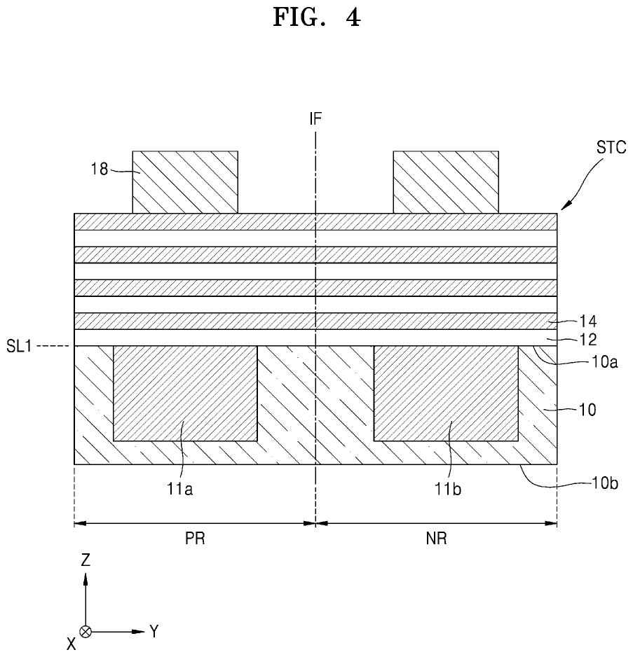

FIGS. 4 to 14 are cross-sectional views illustrating a method of manufacturing nano-sheet stacked structures and a metal dam pattern of the integrated circuit semiconductor device of FIG. 3.

FIGS. 4 to 14 are provided to explain a method of manufacturing the nano-sheet stacked structures and the metal dam pattern of the integrated circuit semiconductor device of FIG. 3, but the inventive concept is not limited thereto. In FIGS. 4 to 14, the same reference numerals as in

FIGS. 1 to 3 refer to the same members/elements. In regard to FIGS. 4 to 14, the same description given with reference to FIGS. 1 to 3 will be briefly described or omitted.

Referring to FIG. 4, a substrate 10 is prepared. The substrate 10 may have a surface 10a and a rear surface 10b. In some embodiments, the substrate 10 may include or be formed of a semiconductor such as Si, Ge, or a compound semiconductor such as SiGe, SiC, GaAs, InAs, or InP. In an embodiment, the substrate 10 may be formed of at least one of a group III-V material and a group IV material.

The group III-V material may be a binary, ternary, or quaternary compound including at least one group III element and at least one group V element. The group III-V material may be a compound including at least one of In, Ga, and Al as a group III element and at least one of As, P, and Sb as a group V element.

For example, the group III-V material may be selected from InP, InzGal-zAs (0≤z≤1), and AlzGal-zAs (0≤z≤1). The binary compound may be, for example, any one of InP, GaAs, InAs, InSb, and GaSb. The ternary compound may be any one of InGaP, InGaAs, AlInAs, InGaSb, GaAsSb, and GaAsP. The group IV material may be Si or Ge. However, the group III-V material and the group IV material that may be used in the integrated circuit semiconductor device according to the technical spirit of the inventive concept are not limited to those exemplified above.

Group III-V materials and group IV materials such as Ge may be used as channel materials for making low-power, high-speed transistors. By using a semiconductor substrate made of a group III-V material, for example, GaAs, having a higher electron mobility than a Si substrate and a semiconductor substrate made of a semiconductor material, for example, Ge, having a higher hole mobility than a Si substrate, a high-performance CMOS may be formed. In some embodiments, the substrate 10 may have a silicon on insulator (SOI) structure. In this embodiment, the substrate 10 is described as using a silicon substrate.

The substrate 10 defines/includes a first region PR and a second region NR. A boundary line IF may be positioned between the first region PR and the second region NR. A first well region 11a and a second well region 11b are respectively formed in the first region PR and the second region NR of the substrate 10. The first well region 11a may be a P-type well region. The first well region 11a is formed by implanting P-type impurities, such as boron, into the substrate 10. The second well region 11b may be an N-type well region. The second well region 11b is formed by implanting an N-type impurity, for example, arsenic or phosphorus, into the substrate 10.

The first region PR is a region in which the first transistor, e.g., the P-type transistor, is to be formed. The first region PR is a region in which the P-type multi-bridge channel transistor is to be formed. The second region NR may be a region in which the second transistor, e.g., an N-type transistor, is to be formed. The second region NR is a region in which an N-type multi-bridge channel transistor is to be formed. For example, a plurality of P-type multi-bridge channel transistors are formed in the first region PR, and a plurality of N-type multi-bridge channel transistors are formed in the second region NR in subsequent steps of the process.

A semiconductor stacked material layer STC is formed in which a sacrificial semiconductor layer 12 and a semiconductor layer 14 for nano-sheets are alternately stacked on the substrate 10 on which the first region PR and the second region NR are formed. The semiconductor stacked material layer STC includes a plurality of sacrificial semiconductor layers 12 and a plurality of nano-sheet semiconductor layers 14. In this embodiment, although it is illustrated that four sacrificial semiconductor layers 12 and four semiconductor layers 14 for nano-sheets are formed on the substrate 10, the inventive concept is not limited thereto.

The semiconductor stacked material layer STC is formed on the surface 10a of the substrate 10. The semiconductor stacked material layer STC may be formed on the first level SL1 of the substrate 10. The sacrificial semiconductor layers 12 constituting the semiconductor stacked material layer STC and the semiconductor layers 14 for nano-sheets may be formed by an epitaxial growth method. The sacrificial semiconductor layers 12 and the semiconductor layers 14 for nano-sheets may be made of different semiconductor materials.

In some embodiments, the sacrificial semiconductor layers 12 may be made of SiGe, and the semiconductor layers 14 for nano-sheets may be made of Si, but are not limited thereto. The sacrificial semiconductor layers 12 may be made of a material that is well etched with respect to the semiconductor layers 14 for nano-sheets. The sacrificial semiconductor layers 12 and the semiconductor layers 14 for nano-sheets may all be formed to have the same thickness, but the inventive concept is not limited thereto.

A first mask pattern 18 is formed on the semiconductor stacked material layer STC. The first mask pattern 18 is formed on the semiconductor stacked material layer STC of the first region PR and the second region NR. The first mask pattern 18 is formed over the first well region 11a of the first region PR and over the second well region 11b of the second region PR.

The first mask pattern 18 includes or may be a hard mask pattern. The first mask pattern 18 may be formed of silicon nitride, polysilicon, a spin-on hardmask (SOH) material, or a combination thereof, but is not limited thereto.

In one embodiment, the SOH material may include a hydrocarbon compound or a derivative thereof having a relatively high carbon content of about 85 wt % to about 99 wt % of the total weight of the SOH material.

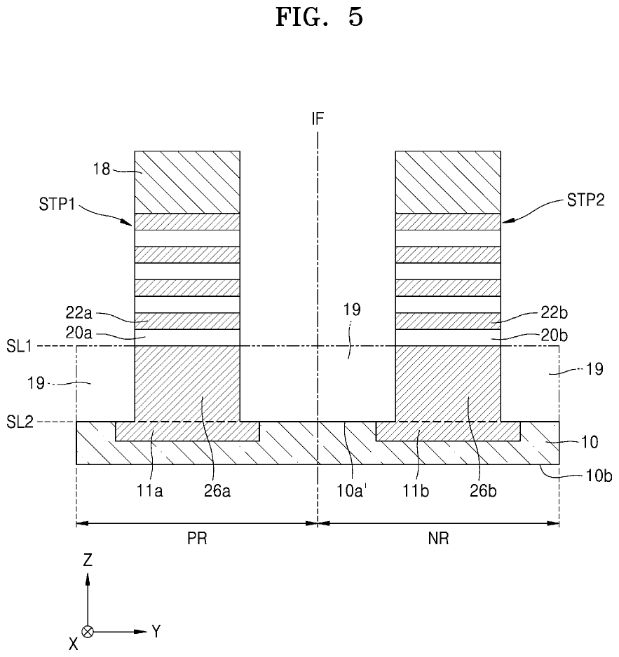

Referring to FIG. 5, the semiconductor stacked material layer STC and a portion of the substrate 10 are etched using the first mask pattern 18 as an etch mask to form a trench 19. Accordingly, active fins 26a and 26b defined by the trench 19 and semiconductor stacked patterns STP1 and STP2 formed on the active fins 26a and 26b are formed on the substrate 10.

The active pins 26a and 26b may be active regions of an integrated circuit semiconductor device. The active fins 26a and 26b may include the first active fin 26a formed in the first region PR and the second active fin 26b formed in the second region NR. The first active fin 26a may have the same body as the first well region 11a. For example, the first active fin 2a and the first well region 11a may be integrally formed as one body. The second active fin 26b may have the same body as the second well region 11b. For example, the second active fin 26b and the second well region 11b may be integrally formed as one body.

The active fins 26a and 26b may be formed by etching a portion of the substrate 10. The active fins 26a and 26b may be formed by etching the surface (refer to 10a of FIG. 4) of the substrate 10, e.g., from the first level SL1 to the second level SL2 of the substrate 10. After the active fins 26a and 26b are formed, the surface 10a′ of the substrate 10 may be at the second level SL2. Accordingly, the active fins 26a and 26b may protrude from the surface 10a′ of the substrate 10.

The semiconductor stacked patterns STP1 and STP2 may include a first semiconductor stacked pattern STP1 formed in the first region PR and a second semiconductor stacked pattern STP2 formed in the second region NR. The first semiconductor stacked pattern STP1 may include first semiconductor patterns 20a and first nano-sheets 22a. The second semiconductor stacked pattern STP2 may include second semiconductor patterns 20b and second nano-sheets 22b.

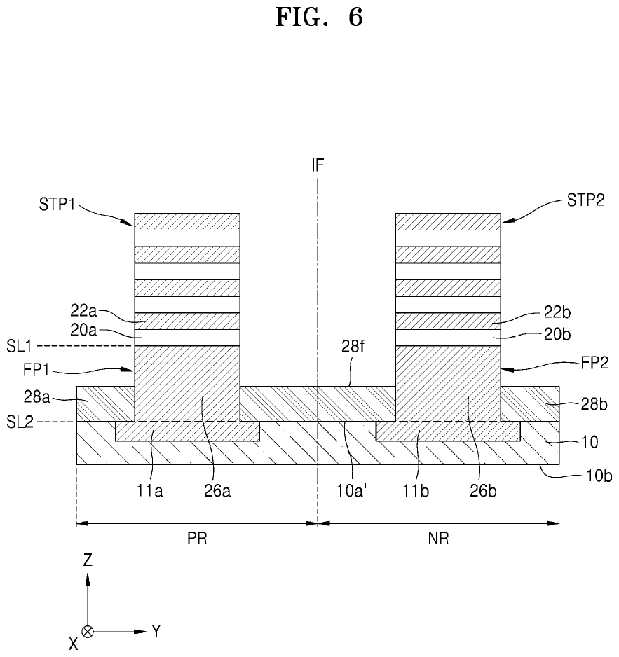

Referring to FIG. 6, the first mask pattern (refer to 18 of FIG. 5) is removed. Then, isolation layers 28a and 28b are formed in the trench (refer to 19 in FIG. 5). The isolation layers 28a and 28b may surround a lower portion of the active fins 26a and 26b. The isolation layers 28a and 28b may include a first isolation layer 28a formed in the first region PR and a second isolation layer 28b formed in the second region NR. The first isolation layer 28a may surround a lower portion of the first active fin 26a. The isolation layer 28b may surround a lower portion of the second active fin 26b. For example, the isolation layers 28a and 28b may respectively contact lower portions of the active fins 26a and 26b.

In some embodiments, the isolation layers 28a and 28b may be formed by filling the trench (refer to 19 of FIG. 5) with an isolation material layer (not shown) and then performing recess etching on the isolation material layer. For the recess etching, dry etching, wet etching, or a combination thereof may be used.

In some embodiments, the isolation layers 28a and 28b may include an oxide film. In some embodiments, the isolation layers 28a and 28b may include an oxide film formed by a deposition process or a coating process. In some embodiments, the isolation layers 28a and 28b may include an oxide film formed by a flowable chemical vapor deposition (FCVD) process or a spin coating process. For example, each of the isolation layers 28a and 28b may be an oxide film.

In certain embodiments, the isolation layers 28a and 28b may include or be formed of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ), but are not limited thereto.

When forming the isolation layers 28a and 28b, by recess etching of an isolation material layer (not shown), the active fins 26a and 26b may protrude from the surface 28f of the isolation layers 28a and 28b. The first active fin 26a may include a first fin protrusion FP1 protruding from the surface 28f of the first isolation layer 28a. The second active fin 26b may include a second fin protrusion FP2 protruding from the surface 28f of the second isolation layer 28b.

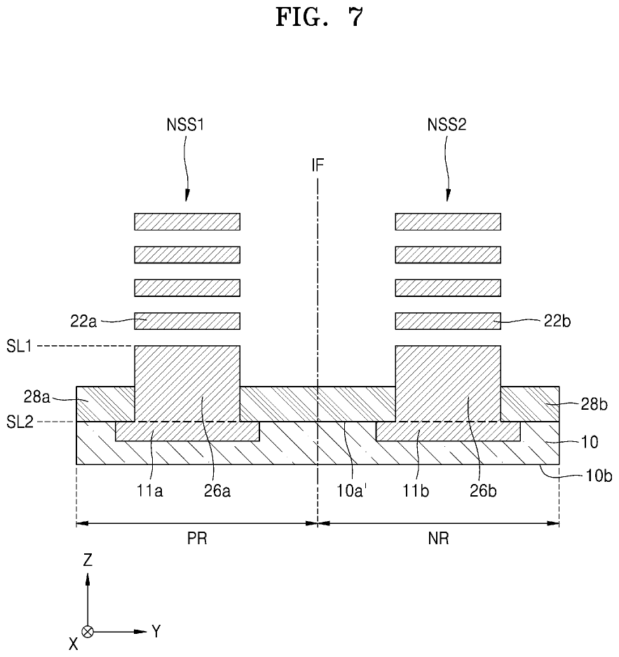

Referring to FIG. 7, the first semiconductor patterns 20a constituting the first semiconductor stacked pattern (refer to STP1 in FIG. 6) and the second semiconductor patterns 20b constituting the second semiconductor stacked pattern STP2 are removed to form nano-sheet stacked structures NSS1 and NSS2.

The nano-sheet stacked structures NSS1 and NSS2 may include a first nano-sheet stacked structure NSS1 formed in the first region PR and a second nano-sheet stacked structure NSS2 formed in the second region NR. The first nano-sheet stacked structure NS is formed on the first active fin 26a and may include a plurality of first nano-sheets 22a spaced apart from each other, e.g., in the vertical direction Z. The second nano-sheet stacked structure NSS2 is formed on the second active fin 26b and may include a plurality of second nano-sheets 22b spaced apart from each other, e.g., in the vertical direction Z.

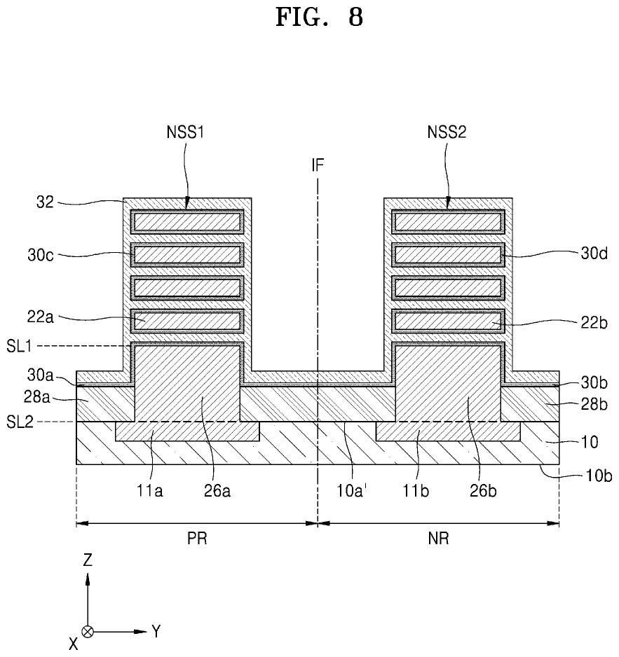

Referring to FIG. 8, gate dielectric layers 30a, 30b, 30c, and 30d are formed to surround the surfaces of the active fins 26a and 26b and the nano-sheets 22a and 22b. The gate dielectric layers 30a and 30b may include a first gate dielectric layer 30a formed on a surface of the first active fin 26a and a second gate dielectric layer 30b formed on the second active fin 26b.

As described above, the first active fin 26a extends in the first direction (X direction) on the substrate 10. The first gate dielectric layer 30a is formed to extend from a top surface of the first active fin 26a in the second direction (Y direction) onto the first isolation layer 28a. The second active fin 26b extends on the substrate 10 in the first direction (X direction). The second gate dielectric layer 30b is formed to extend from a top surface of the second active fin 26b in the second direction (Y direction) onto the first isolation layer 28a.

The gate dielectric layers 30c and 30d may include a third gate dielectric layer 30c surrounding (i.e., covering) the first nano-sheets 22a and a fourth gate dielectric layer 30d surrounding (i.e., covering) the second nano-sheets 22b. The first nano-sheets 22a may be stacked to be spaced apart from the first gate dielectric layer 30a. The second nano-sheets 22b may be stacked to be spaced apart from the second gate dielectric layer 30b.

The gate dielectric layers 30a, 30b, 30c, and 30d may include a high-k film. For example, each of the gate dielectric layers 30a, 30b, 30c, and 30d may be a high-k film. The high-k film may be made of a material having a higher dielectric constant than the silicon oxide film. For example, the high-k film may have a dielectric constant of about 10 to about 25.

The high-k film may be made of a material selected from hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, lead zinc niobate, and a combination thereof, but the materials constituting the high-k film are not limited to those exemplified above.

The high-k film may be formed by an atomic layer deposition (ALD), chemical vapor deposition (CVD), or physical vapor deposition (PVD) process. The high-k film may have a thickness of about 10 Å to about 40 Å, but is not limited thereto.

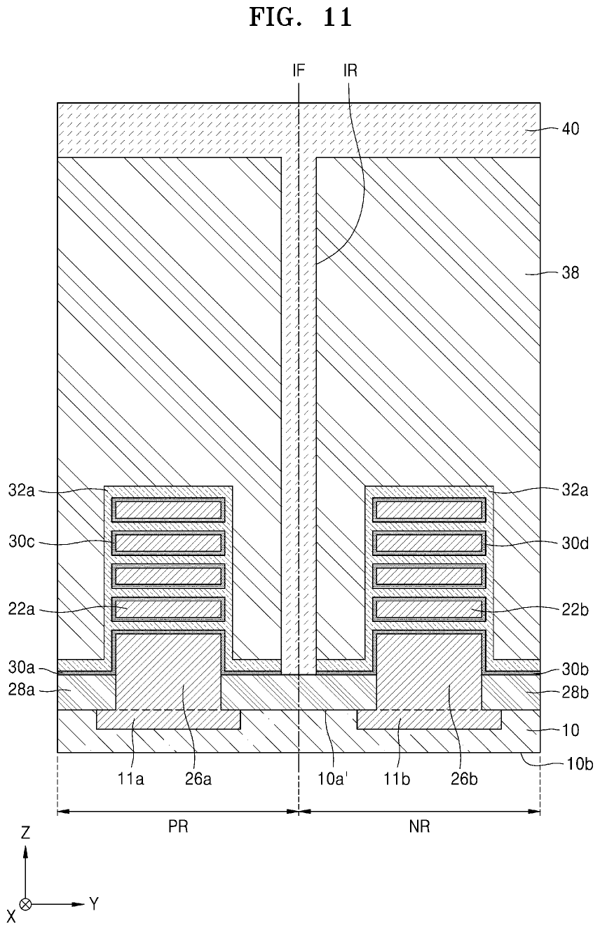

Subsequently, a first metal layer 32 is formed over the gate dielectric layers 30a, 30b, 30c, and 30d, between the first nano-sheets 22a, and between the second nano-sheets 22b. The first metal layer 32 is formed to be buried between the first nano-sheets 22a and between the second nano-sheets 22b. The first metal layer 32 is formed of a material that is more easily etched than a second metal layer (refer to 40 of FIG. 11) to be formed later. The first metal layer 32 includes or may be a TiN film. The first metal layer 32 is formed to surround the upper portions of the nano-sheet stacked structures NSS1 and NSS2. For example, the first metal layer 32 may be formed on top surfaces of the first and second nano-sheet stacked structures NSS1 and NSS2.

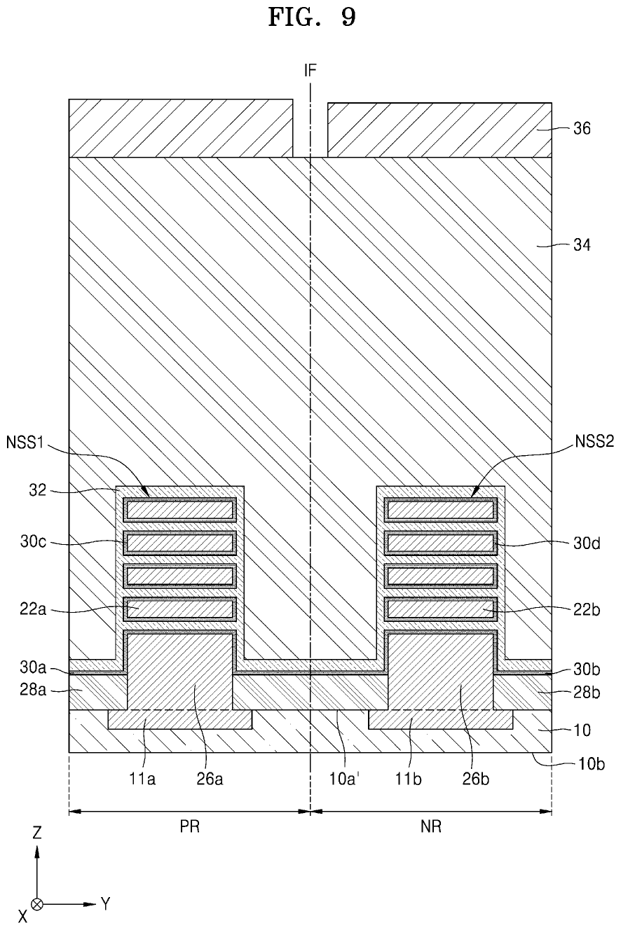

Referring to FIG. 9, a second mask layer 34 is formed to have a thickness sufficient to cover the nano-sheet stacked structures NSS1 and NSS2 on the first metal layer 32. The second mask layer 34 may be a planarization layer. The second mask layer 34 may be an optical planarization layer. The second mask layer 34 may be a material layer that may be patterned by a photolithography process. The second mask layer 34 may have a thickness of about 1000 Å to about 4000 Å, but is not limited thereto.

The second mask layer 34 may include or may be a hard mask layer. The second mask layer 34 may be formed of silicon nitride, polysilicon, a spin-on hardmask (SOH) material, or a combination thereof, but is not limited thereto. In one embodiment, the SOH material may include or be formed of a hydrocarbon compound or a derivative thereof having a relatively high carbon content of about 85 wt % to about 99 wt %, based on the total weight of the SOH material.

A third mask pattern 36 is formed on the second mask layer 34. The third mask pattern 36 may be formed as a photoresist pattern. The third mask pattern 36 may be formed on the first region PR and the second region NR.

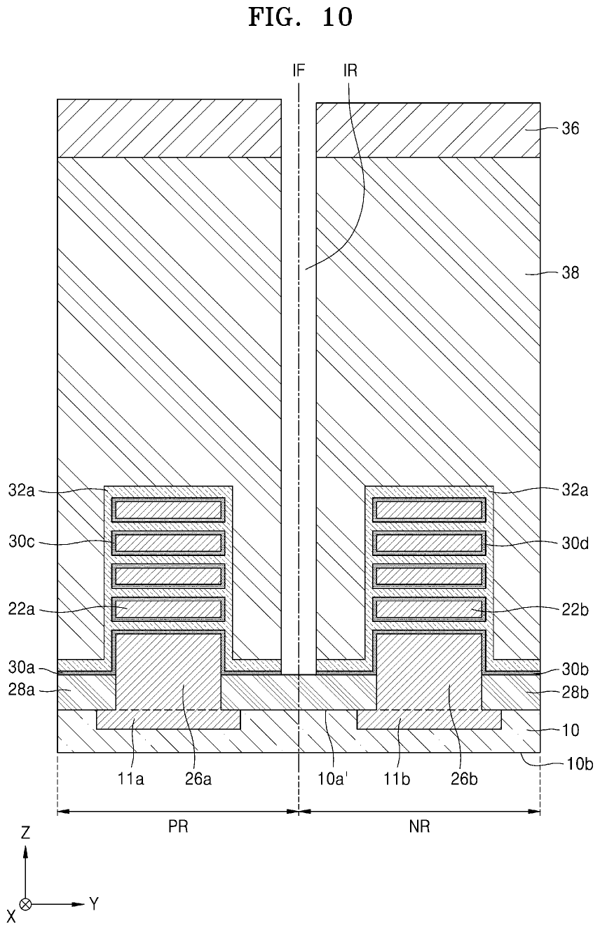

Referring to FIG. 10, the second mask layer 34 and the first metal layer 32 are etched using the third mask pattern 36 as an etch mask to form a second mask pattern 38 and a first metal pattern 32a. A portion of the first gate dielectric layer 30a and a portion of the second gate dielectric layer 30b may be removed at the boundary line IF and its vicinity by the etching process. In some embodiments, when the first metal pattern 32a and the second mask pattern 38 are formed, the first and second gate dielectric layers 30a and 30b near the boundary line IF may not be etched.

According to the formation of the first metal pattern 32a and the second mask pattern 38, an isolation region IR separating the first region PR and the second region NR may be formed near the boundary line IF between the first region PR and the second region NR. One sidewall of the first metal pattern 32a and the second mask pattern 38 in contact with or facing the isolation region IR may have a vertical profile on the surface of the substrate 10 in a vertical direction.

The isolation region IR may be an exposed region exposing the isolation layers 28a and 28b or the first and second gate dielectric layers 30a and 30b. The isolation region IR may be a hole region formed in the second mask layer 34 and the first metal layer 32 near the boundary line IF between the first region PR and the second region NR.

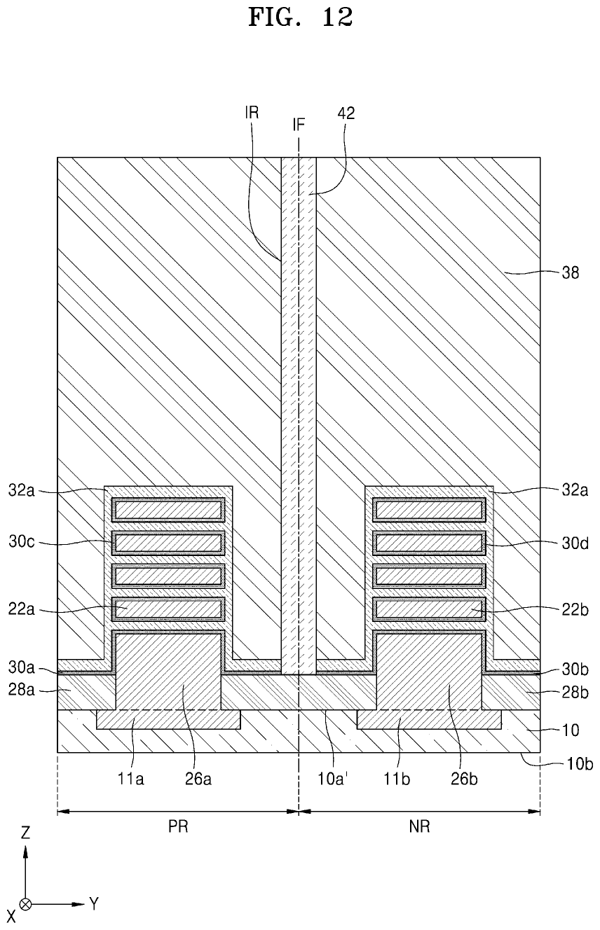

Referring to FIGS. 11 and 12, the third mask pattern (refer to 36 of FIG. 10) is removed. Next, as shown in FIG. 11, a second metal layer 40 is formed on the second mask pattern 38 to fill the inside of the isolation region IR. The second metal layer 40 is formed of a material having an etch selectivity compared to the first metal layer 32. For example, the second metal layer 40 may have a higher etch rate than the first metal layer 32 with respect to certain etchant, e.g., in a subsequent etching process. The second metal layer 40 may include or be formed of a single layer or a composite layer of TaN, TiAlN, or TiAlC.

Subsequently, as shown in FIG. 12, the second metal layer 40 is planarized to form a second metal pattern 42 buried in the isolation region IR. For example, the second metal pattern 42 may fill the isolation region IR and may be disposed between the first region PR and the second region NR, e.g., in a plan view. The second metal pattern 42 may become a metal dam pattern through a post process, e.g., in a subsequent process. The planarization of the second metal layer 40 may be performed using an etch-back process or a chemical mechanical polishing process. The top surface of the second metal pattern 42 may be at the same plane as the top surface of the second mask pattern 38.

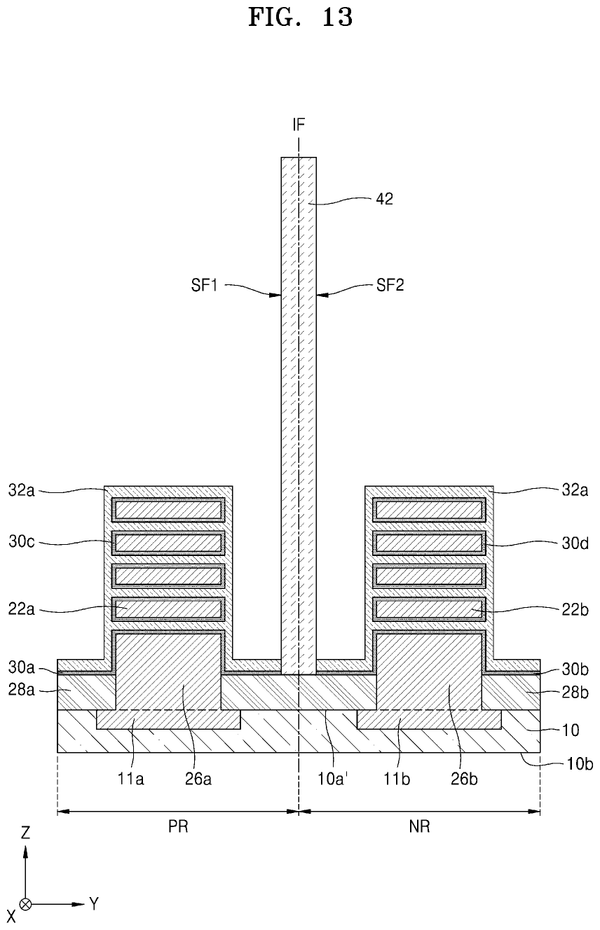

Referring to FIGS. 13 and 14, as shown in FIG. 13, the second mask pattern 38 is removed. In this case, the first metal pattern 32a is exposed in the first region PR and the second region NR, and a second metal pattern 42 may be formed near the boundary line IF (e.g., at the boundary) between the first region PR and the second region NR. Both sidewalls SF1 and SF2 of the second metal pattern 42 may have a vertical profile on the surface 10a of the substrate 10 in the vertical direction (i.e., the Z direction). For example, both sidewalls SF1 and SF2 respectively facing the first region PR and the second region NR may extend in the third direction Z, e.g., in the vertical direction.

Subsequently, as shown in FIG. 14, the first metal pattern (refer to 32a of FIG. 13) is removed in the first region PR and the second region NR by a wet etching method. The etching of the first metal pattern (refer to 32a of FIG. 13) may be performed using a wet etchant, for example, an H₂O₂ etchant. When the first metal pattern (refer to 32a of FIG. 13) is etched, the second metal pattern 42 may not be etched. The etch selectivity between the first metal pattern (refer to 32a in FIG. 13) and the second metal pattern 42 may be 10:1 to 30:1.

By removing the first metal pattern (refer to 32a in FIG. 13), a film may not be formed between the first nano-sheets 22a constituting the first nano-sheet stacked structure NSS1 and between the first active fin 26a and the lowermost first nano-sheet 22a. In addition, by removing the first metal pattern (refer to 32a in FIG. 13), a film may not be formed between the second nano-sheets 22b of the second nano-sheet stacked structure NSS2 and between the second active fin 26b and the lowermost second nano-sheet 22b. For example, by the etching process, the first metal pattern 32a disposed between the first nano-sheets 22a and between the lower most first nano-sheet 22a and the first active fin 26a may be removed, and the first metal pattern 32a disposed between the second nano-sheets 22b and between the lower most second nano-sheet 22b and the second active fin 26b may be removed.

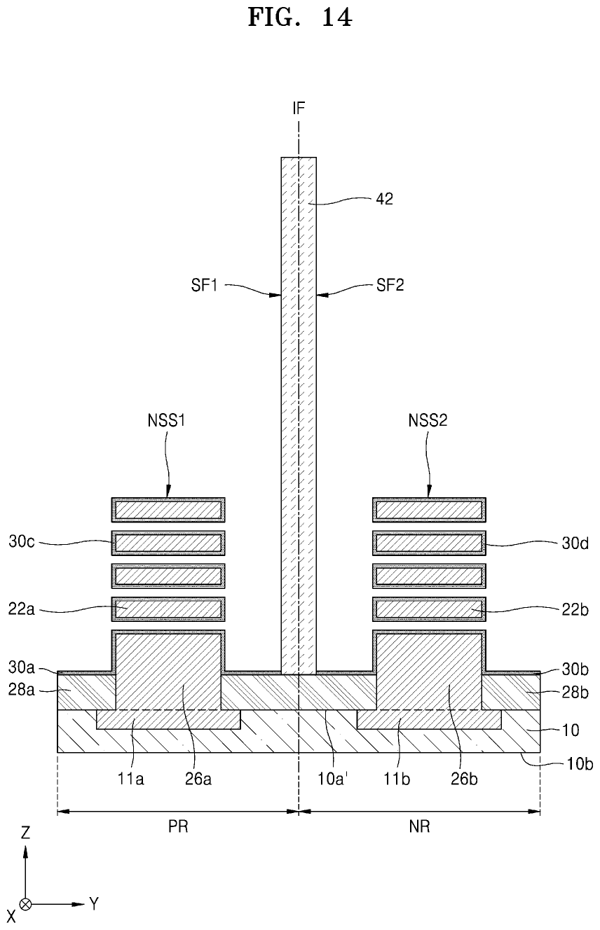

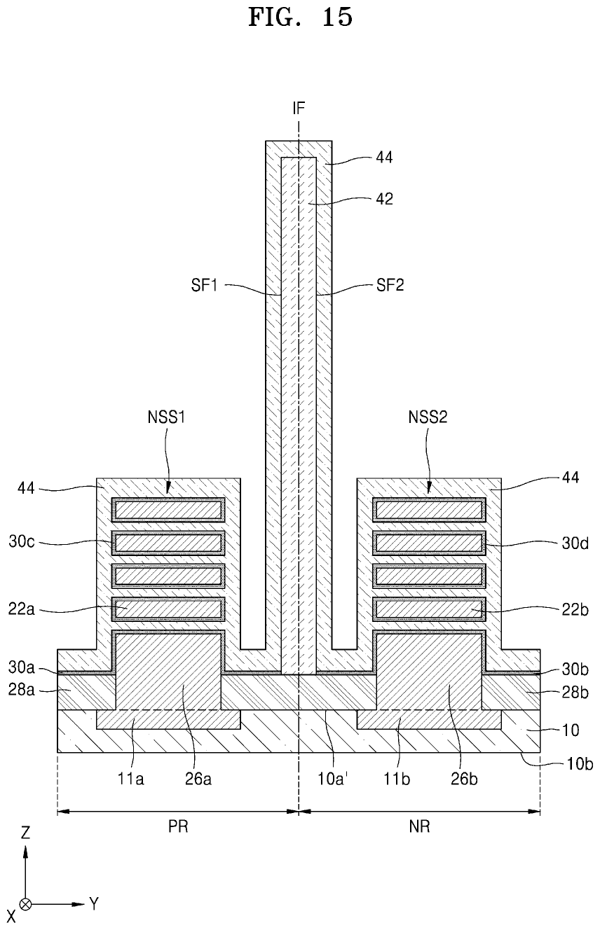

FIGS. 15 to 22 are cross-sectional views illustrating a method of manufacturing barrier metal layers and gate electrodes of the integrated circuit semiconductor device of FIG. 3.

For example, FIGS. 15 to 22 are provided to explain a method of manufacturing the barrier metal layers and gate electrodes of the integrated circuit semiconductor device of FIG. 3, but the inventive concept is not limited thereto. In FIGS. 15 to 22, the same reference numerals as in FIGS. 1 to 3 refer to the same members/elements. In FIGS. 15 to 22, the same descriptions given with respect to FIGS. 1 to 3 will be briefly described or omitted.

Referring to FIG. 15 , a third metal layer 44 covering the first nano-sheet stacked structure NSS1, the second nano-sheet stacked structure NSS2, and the second metal pattern 42 is formed. The third metal layer 44 is formed of TiN.

The third metal layer 44 may be buried/formed between the first nano-sheets 22a constituting the first nano-sheet stacked structure NSS1 and between the first active fin 26a and the lowermost first nano-sheet 22a. The third metal layer 44 may be formed between the first gate dielectric layer 30a on the first active fin 26a and the third gate dielectric layer 30c on the lowermost first nano-sheet 22a, and between the third gate dielectric layers 30c on the first nano-sheets 22a.

The third metal layer 44 may be buried/formed between the second nano-sheets 22b constituting the second nano-sheet stacked structure NSS2 and between the second active fin 26b and the lowermost second nano-sheet 22b. The third metal layer 44 may be formed between the second gate dielectric layer 30b on the second active fin 26b and the fourth gate dielectric layer 30d on the lowermost second nano-sheet 22b, and between the fourth gate dielectric layers 30d on the second nano-sheets 22b. The third metal layer 44 may be formed on the entire surface of the second metal pattern 42. The third metal layer 44 may be formed on both sidewalls SF1 and SF2 of the second metal pattern 42.

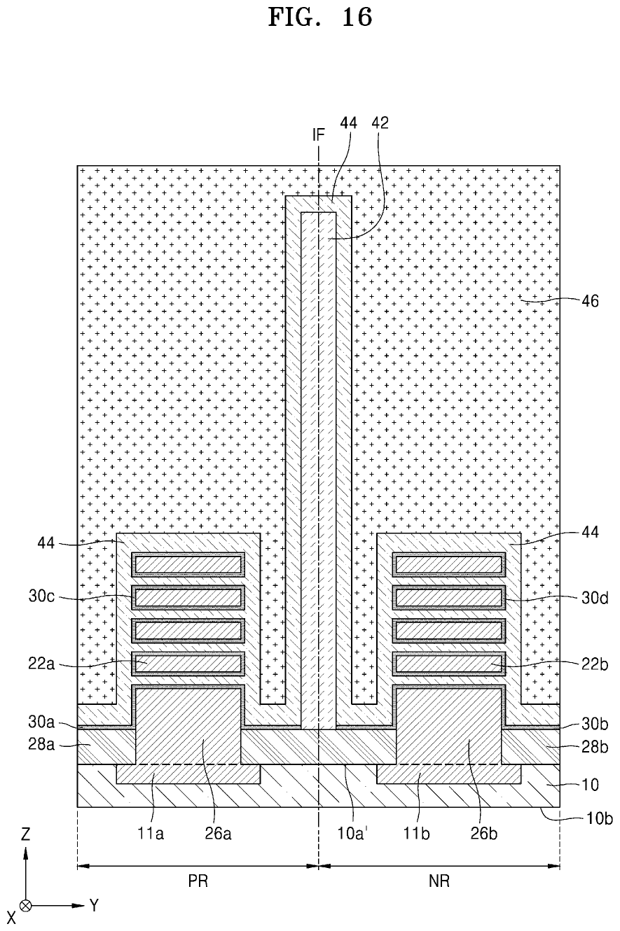

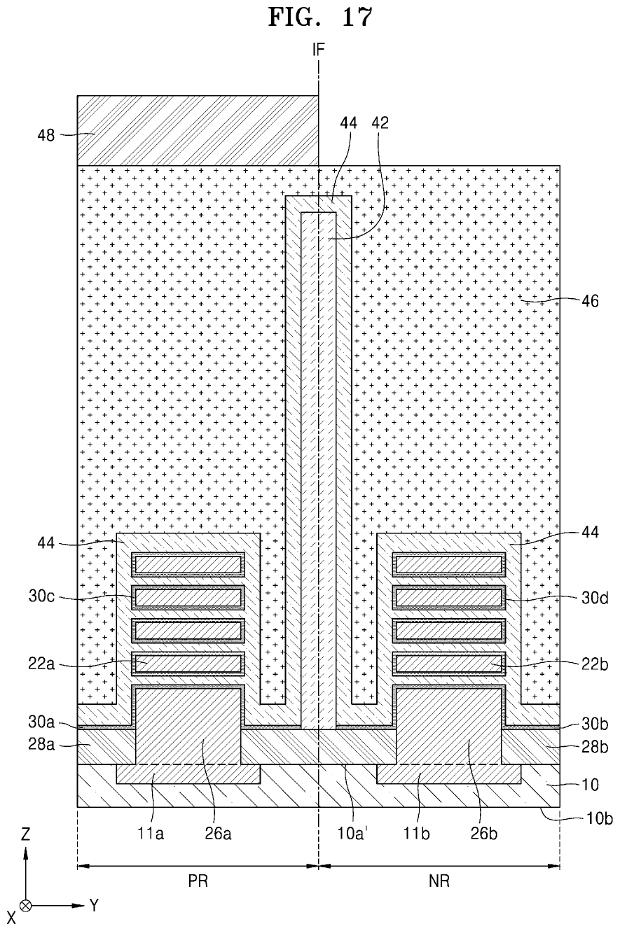

Referring to FIGS. 16 and 17, as shown in FIG. 16, a fourth mask layer 46 is formed on the third metal layer 44 to have a sufficient thickness to cover the nano-sheet stacked structures NSS1 and NSS2 and the second metal pattern 42. The fourth mask layer 46 may be a planarization layer. For example, a top surface of the fourth mask layer 46 may be at a higher level than top surfaces of the nano-sheet stacked structures NSS1 and NSS2 and the second metal pattern 42 in the vertical direction.

The fourth mask layer 46 may be an optical planarization layer. The fourth mask layer 46 may be a material layer that may be patterned by a photolithography process. The fourth mask layer 46 may have a thickness of about 1000 Å to about 4000 Å, but is not limited thereto. The fourth mask layer 46 may be formed of the same material as the second mask layer 34 described above.

As shown in FIG. 17, a fifth mask pattern 48 is formed on the fourth mask layer 46. The fifth mask pattern 48 may be formed as a photoresist pattern. The fifth mask pattern 48 may be formed on the first region PR.

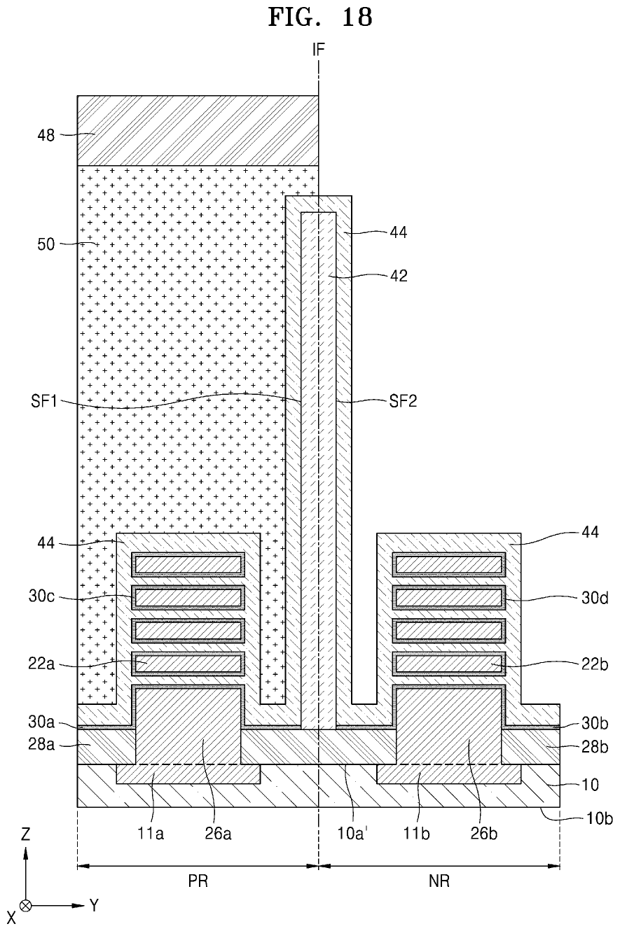

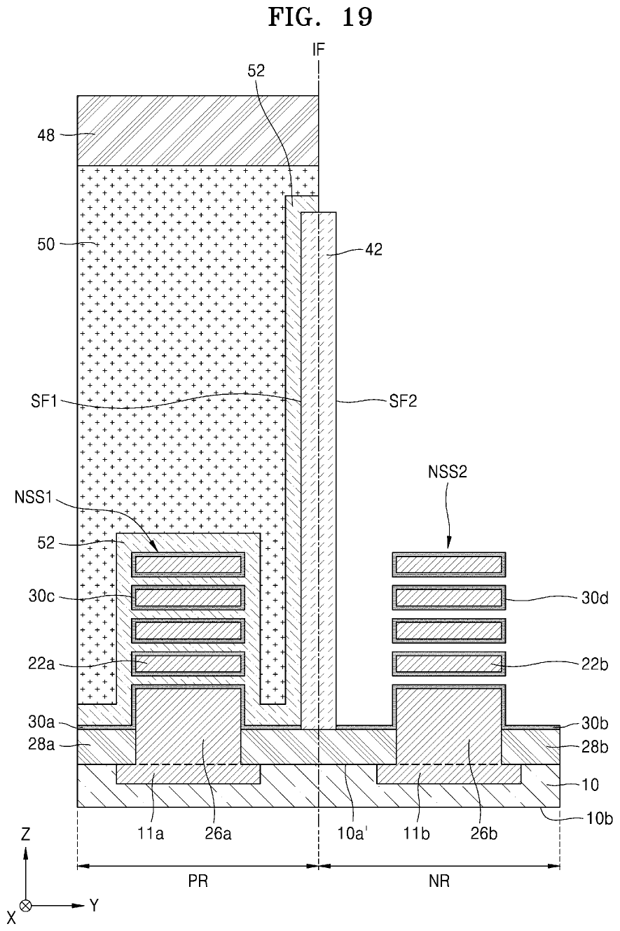

Referring to FIGS. 18 and 19, as shown in FIG. 18 , the fourth mask layer 46 on the second region NR is etched and removed using the fifth mask pattern 48 as an etch mask. In this case, the fourth mask layer 46 is left only in the first region PR to form the fourth mask pattern 50. In the second region NR, the third metal layer 44 formed on the other sidewall SF2 of the second metal pattern 42 and on the second nano-sheet stacked structure NSS2 is exposed by removing the fourth mask layer 46 formed in the second region NR.

As shown in FIG. 19, the third metal layer 44 of the second region NR is etched by a wet etching method using the fifth mask pattern 48 and the fourth mask pattern 50 as an etch mask to remove the third metal layer 44 formed in the second region NR. As the third metal layer 44 in the second region NR is etched, a third metal pattern 52 is formed in the first region PR. The third metal pattern 52 is formed on the one sidewall SF1 of the second metal pattern 42 while covering the first nano-sheet stacked structure NSS1.

The etching of the third metal layer 44 of the second region NR may be performed using a wet etchant, for example, an H₂O₂ etchant. When the third metal layer 44 of the second region NR is etched, the second metal pattern 42 may not be etched. When the third metal layer 44 of the second region NR is etched, the second metal pattern 42 may be an etch barrier layer or an etch stop layer that prevents etching of the first region NR. The etch selectivity between the third metal layer 44 and the second metal pattern 42 may be 10:1 to 30:1.

By removing the third metal layer 44 of the second region NR, a film may not be formed between the second nano-sheets 22b of the second nano-sheet stacked structure NSS2 and between the second active fin 26b and the lowermost second nano-sheet 22b. For example, the third metal layer 44 may be removed from between the second nano-sheets 22b of the second nano-sheet stacked structure NSS2 and between the second active fin 26b and the lowermost second nano-sheet 22b.

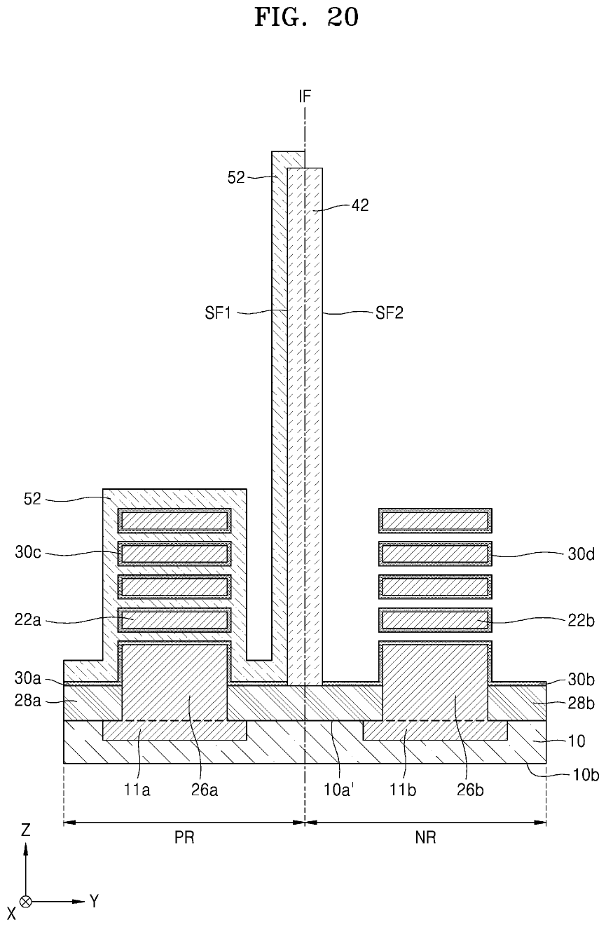

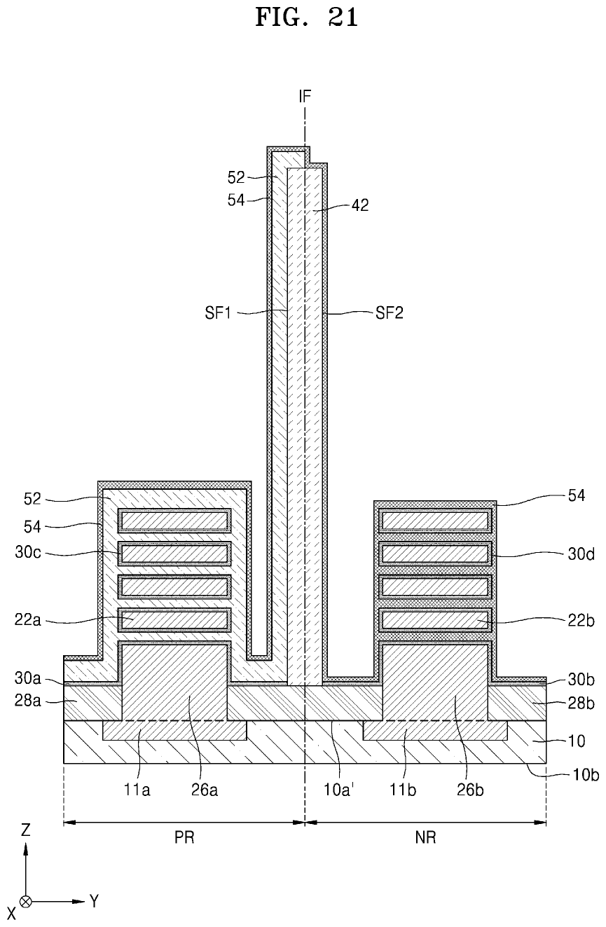

Referring to FIGS. 20 and 21, as shown in FIG. 20, the fifth mask pattern 48 and the fourth mask pattern 50 of the first region PR are removed. Subsequently, as shown in FIG. 21, a fourth metal layer 54 is formed on the entire surface of the first region PR and the second region NR. The fourth metal layer 54 may include or be formed of a single layer or a composite layer of TiN, TiAlN, and TiAlC.

The fourth metal layer 54 is formed on an upper portion of the third metal pattern 52 on the first nano-sheet stacked structure NSS1, an upper portion of the third metal pattern 52 on the one sidewall SF1 of the second metal pattern 42, an upper portion of the other sidewall SF2 of the second metal pattern 42, and the second nano-sheet stacked structure NSS2. The fourth metal layer 54 may be formed and fill spaces between the second nano-sheets 22b of the second nano-sheet stacked structure NSS2 and between the second active fin 26b and the lowermost second nano-sheet 22b.

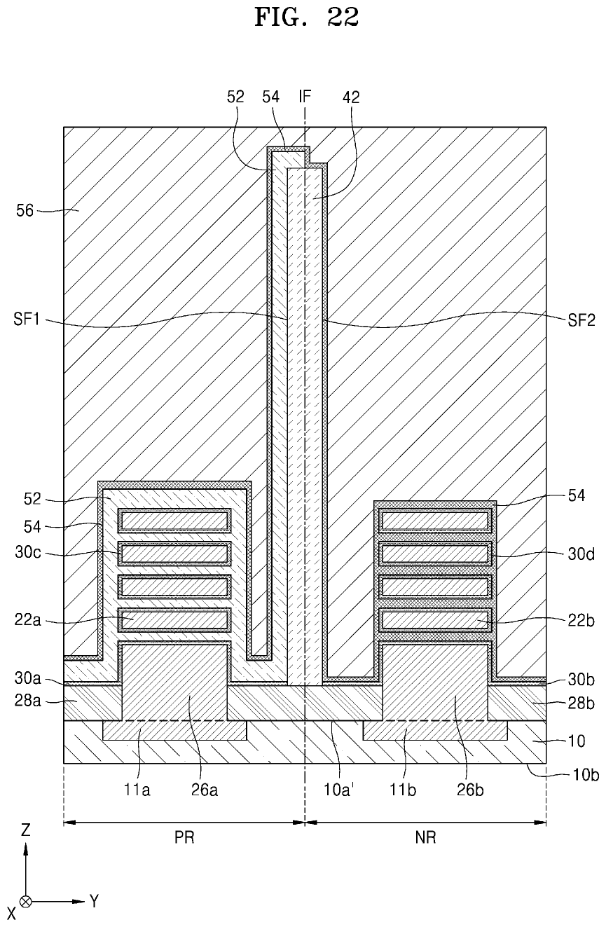

Referring to FIG. 22, a fifth metal layer 56 is formed on the entire surface of the first region PR and the second region NR. The fifth metal layer 56 may include or be formed of a single layer or a composite layer of TiN, TiAlN, and TiAlC. The fifth metal layer 56 is formed to have a sufficient thickness to cover the first nano-sheet stacked structure NSS1, the second metal pattern 42, and the second nano-sheet stacked structure NSS2. For example, a top surface of the fifth metal layer 56 may be at a higher level than top surfaces of the first nano-sheet stacked structure NSS1, the second metal pattern 42 and the second nano-sheet stacked structure NSS2 in the vertical direction.

The fifth metal layer 56 is formed on an upper portion of the fourth metal layer 54 on the first nano-sheet stacked structure NSS1, an upper portion of the fourth metal layer 54 on the one sidewall SF1 of the second metal pattern 42, an upper portion of the fourth metal layer 54 on the other sidewall SF2 of the second metal pattern 42, and the fourth metal layer 54 on the second nano-sheet stacked structure NSS2.

Subsequently, as shown in FIG. 3, the fifth metal layer 56, the fourth metal layer 54, the third metal pattern 52, and the second metal pattern 42 are etched back. In this way, in the first region PR, first and second barrier metal layers 52pa and 54pa and a first gate electrode 56pa may be formed on the first nano-sheet stacked structure NSS1. The first and second barrier metal layers 52pa and 54pa may be formed by etching the third metal pattern 52 and the fourth metal layer 54. The first gate electrode 56pa may be formed by etching the fifth metal layer 56.

A third barrier metal layer 54pb and a second gate electrode 56pb may be formed on the second nano-sheet stacked structure NSS2 in the second region NR. The third barrier metal layer 54pb may be formed by etching the fourth metal layer 54. The second gate electrode 56pb may be formed by etching the fifth metal layer 56.

In addition, a metal dam pattern 42P is formed in the isolation region IR near the boundary line IF between the first region PR and the second region NR. The metal dam pattern 42P may be formed by the second metal pattern 42. First and second barrier metal layers 52pa and 54pa may be formed on the one sidewall SF1 of the metal dam pattern 42P, and a third barrier metal layer 54pb may be formed on the other sidewall SF2 of the metal dam pattern 42P.

FIG. 23 is a block diagram illustrating a configuration of a semiconductor chip including an integrated circuit semiconductor device according to an embodiment of the inventive concept.

For example, a semiconductor chip 200 may include a logic region 202, an SRAM region 204, and an input/output region 206. The logic region 202 may include a logic cell region 203. The SRAM region 204 may include an SRAM cell region 205 and an SRAM peripheral circuit region 208. A first transistor 210 may be arranged in the logic cell region 203, and a second transistor 212 may be arranged in the SRAM cell region 205. A third transistor 214 may be formed in the SRAM peripheral circuit region 208, and a fourth transistor 216 may be arranged in the input/output region 206.

The semiconductor chip 200 may include or may be an integrated circuit semiconductor device 100 according to an embodiment of the inventive concept. In some embodiments, the first transistor 210, the second transistor 212, the third transistor 214, and the fourth transistor 216 may include or may be the first multi-bridge channel transistor MBC1 or the second multi-bridge channel transistor MBC2 described above. For example, one or more of the logic region 202, the SRAM region 204, and the input/output region 206 may include the first multi-bridge channel transistor MBC1 and/or the second multi-bridge channel transistor MBC2 described above.

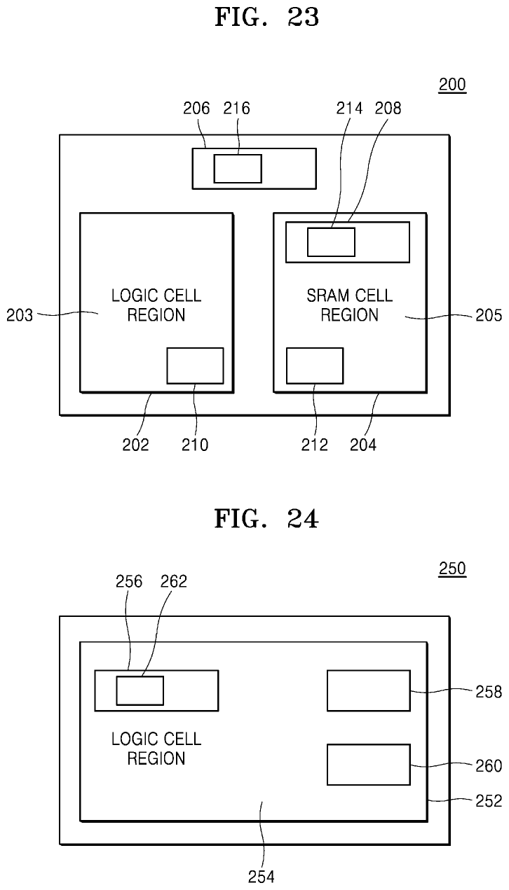

FIG. 24 is a block diagram illustrating a configuration of a semiconductor chip including an integrated circuit semiconductor device according to an embodiment of the inventive concept.

For example, the semiconductor chip 250 may include a logic region 252. The logic region 252 may include a logic cell region 254 and an input/output region 256. A first transistor 258 and a second transistor 260 may be arranged in the logic cell region 254. The first transistor 258 and the second transistor 260 may be transistors of different conductivity types. A third transistor 262 may be arranged in the input/output region 256.

The semiconductor chip 250 may include or may be an integrated circuit semiconductor device 100 according to an embodiment of the inventive concept. In some embodiments, the first transistor 258, the second transistor 260, and the third transistor 262 may include or may be the first multi-bridge channel transistor MBC1 or the second multi-bridge channel transistor MBC2 described above. For example, the logic cell region 254 and/or the input/output region 256 may include the first multi-bridge channel transistor MBC1 and/or the second multi-bridge channel transistor MBC2 described above.

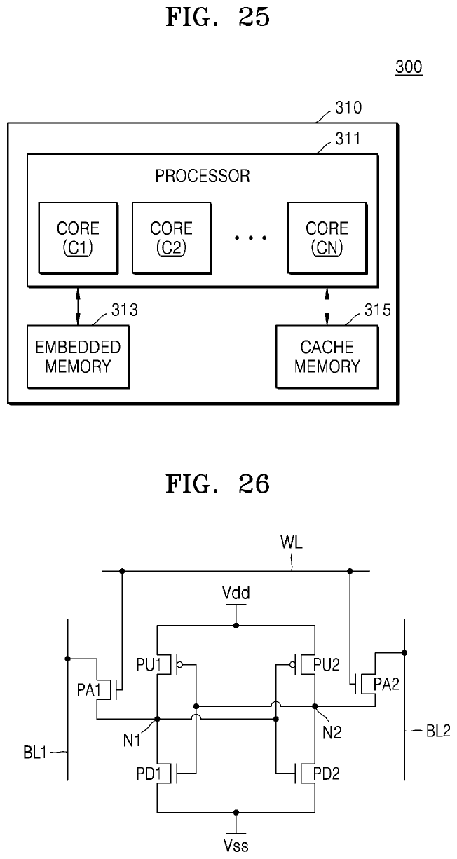

FIG. 25 is a block diagram illustrating a configuration of an electronic device including an integrated circuit semiconductor device according to an embodiment of the inventive concept.

For example, the electronic device 300 may include a system-on-chip 310. The system on chip 310 may include a processor 311, an embedded memory 313, and a cache memory 315. The processor 311 may include one or more processor cores C1 to CN. The processor cores C1 to CN may process data and signals. The processor cores C1 to CN may include the integrated circuit semiconductor device 100 according to embodiments of the inventive concept.

The electronic device 300 may perform a unique function by using the processed data and signals. For example, the processor 311 may be an application processor. The embedded memory 313 may exchange first data DAT1 with the processor 311. The first data DAT1 is data processed or to be processed by the processor cores C1 to CN. The embedded memory 313 may manage the first data DAT1. For example, the embedded memory 313 may buffer the first data DAT1. The embedded memory 313 may operate as a buffer memory or a working memory of the processor 311.

The embedded memory 313 may be an SRAM. SRAM may operate at higher speeds than DRAM. When the SRAM is embedded in the system on chip 310, the electronic device 300 having a small size and operating at a high speed may be implemented. Furthermore, when the SRAM is embedded in the system-on-chip 310, the consumption of active power of the electronic device 300 may be reduced.

For example, the SRAM may include or may be the integrated circuit semiconductor device 100 according to embodiments of the inventive concept. The cache memory 315 may be mounted on the system on chip 310 together with the processor cores C1 to CN. The cache memory 315 may store cache data DATc. The cache data DATc may be data used by the processor cores C1 to CN. The cache memory 315 has a small storage capacity, but may operate at very high speeds.

For example, the cache memory 315 may include or may be a static random access memory (SRAM) including or formed of the integrated circuit semiconductor device 100 according to embodiments of the inventive concept. When the cache memory 315 is used, the number and time of the processor 311 accessing the embedded memory 313 may be reduced. Accordingly, when the cache memory 315 is used, the operating speed of the electronic device 300 may be increased. For ease of understanding, in FIG. 25, the cache memory 315 is illustrated as a separate component from the processor 311. However, the cache memory 315 may be included in the processor 311 in certain embodiments.

FIG. 26 is an equivalent circuit diagram of an SRAM cell according to an embodiment of the inventive concept.

For example, the SRAM cell may be implemented through the integrated circuit semiconductor device 100 according to an embodiment of the inventive concept. As an example, the SRAM cell may be applied to the embedded memory 313 and/or the cache memory 315 described with reference to FIG. 25.

The SRAM cells may include a first pull-up transistor PU1, a first pull-down transistor PD1, a second pull-up transistor PU2, a second pull-down transistor PD2, a first access transistor PA1, and a second access transistor PA2.

The first and second pull-up transistors PU1 and PU2 may be P-type MOS transistors, and the first and second pull-down transistors PD1 and PD2 and the first and second access transistors PA1 and PA2 may be N-type MOS transistors.

The first pull-up transistor PU1 and the first pull-down transistor PD1 may constitute a first inverter. The gate electrodes (gates) connected to each other of the first pull-up and first pull-down transistors PU1 and PD1 may correspond to the input terminal of the first inverter, and the first node N1 may correspond to the output terminal of the first inverter.

The second pull-up transistor PU2 and the second pull-down transistor PD2 may constitute a second inverter. The gate electrodes (gates) connected to each other of the second pull-up and second pull-down transistors PU2 and PD2 may correspond to the input terminal of the second inverter, and the second node N2 may correspond to the output terminal of the second inverter.

The first and second inverters may be combined to form a latch structure. The gate electrodes of the first pull-up and first pull-down transistors PU1 and PD1 may be electrically connected to the second node N2, and the gates of the second pull-up and second pull-down transistors PU2 and PD2 may be electrically connected to the first node N1.

A first source/drain of the first access transistor PA1 may be connected to the first node N1, and a second source/drain of the first access transistor PA1 may be connected to a first bit line BL1. A first source/drain of the second access transistor PA2 may be connected to the second node N2, and a second source/drain of the second access transistor PA2 may be connected to the second bit line BL2.

The gate electrodes of the first and second access transistors PA1 and PA2 may be electrically connected to a word line WL. Accordingly, an SRAM cell may be implemented using the integrated circuit semiconductor device 100 according to embodiments of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit semiconductor device comprising:
a first region including first active fins extending in a first direction and spaced apart from each other in a second direction perpendicular to the first direction, and first transistors including first gate electrodes extending in the second direction on the first active fins and spaced apart from each other in the first direction;
a second region arranged in contact with the first region in the second direction, wherein the second region comprises second active fins extending in the first direction and spaced apart from each other in the second direction, and second transistors including second gate electrodes extending in the second direction on the second active fins and spaced apart from each other in the first direction; and
a plurality of metal dams positioned at a boundary of the first region and the second region to physically separate the first gate electrodes and the second gate electrodes in the second direction,
wherein the metal dams, the first gate electrodes, and the second gate electrodes are electrically connected in the second direction.

2. The integrated circuit semiconductor device of claim 1, wherein the metal dams are spaced apart from each other in the first direction.

3. The integrated circuit semiconductor device of claim 1, wherein the metal dams are positioned at the same distance from the first active fins and the second active fins in the second direction.

4. The integrated circuit semiconductor device of claim 1, wherein the first gate electrodes and the second gate electrodes are formed of the same material.

5. The integrated circuit semiconductor device of claim 1, further comprising:
first nano-sheet stacked structures positioned on the first active fins, and
second nano-sheet stacked structures positioned on the second active fins,
wherein the metal dams are positioned between the first nano-sheet stacked structures and the second nano-sheet stacked structures in the second direction.

6. The integrated circuit semiconductor device of claim 5, wherein the first nano-sheet stacked structures comprise a plurality of first nano-sheets spaced apart from each other in a vertical direction, and
wherein the second nano-sheet stacked structures comprise a plurality of second nano-sheets spaced apart from each other in a vertical direction.

7. The integrated circuit semiconductor device of claim 1, wherein the first transistors and the second transistors are surrounded by an isolation layer formed on a substrate, and
wherein the metal dams are arranged on the isolation layer.

8. The integrated circuit semiconductor device of claim 1, wherein the first transistors are P-type multi-bridge channel transistors, and the second transistors are N-type multi-bridge channel transistors.

9. An integrated circuit semiconductor device comprising:
a first region including a first active fin extending in a first direction on a substrate, a first gate dielectric layer extending from a top surface of the first active fin onto a first isolation layer in a second direction perpendicular to the first direction, and a first gate electrode extending in the second direction on the first gate dielectric layer;
a second region arranged on the substrate in contact with the first region in the second direction, wherein the second region comprises a second active fin extending in the first direction, a second gate dielectric layer extending from a top surface of the second active fin onto a second isolation layer in the second direction, and a second gate electrode extending in the second direction on the second gate dielectric layer; and
a metal dam positioned at a boundary of the first region and the second region to physically separate the first gate electrode and the second gate electrode in the second direction,
wherein the metal dam, the first gate electrode, and the second gate electrode are electrically connected to each other.

10. The integrated circuit semiconductor device of claim 9, wherein the metal dam is in contact with the first isolation layer and the second isolation layer.

11. The integrated circuit semiconductor device of claim 9, wherein the metal dam is positioned at the same distance from the first active fin and the second active fin.

12. The integrated circuit semiconductor device of claim 9, wherein the metal dam is a metal dam pattern,
wherein one sidewall of the metal dam pattern extends in a direction perpendicular to a surface of the substrate, and
wherein a lower width of the metal dam pattern in the second direction is the same as an upper width of the metal dam pattern in the second direction.

13. The integrated circuit semiconductor device of claim 9, wherein the first active fin comprises a first fin protrusion protruding from a surface of the first isolation layer, and
wherein the second active fin comprises a second fin protrusion protruding from a surface of the second isolation layer.

14. The integrated circuit semiconductor device of claim 9, wherein the metal dam is a metal dam pattern,
wherein, in the first region, first and second barrier metal layers are further formed on one sidewall of the metal dam pattern, and
wherein, in the second region, a third barrier metal layer is further formed on the other sidewall of the metal dam pattern.

15. The integrated circuit semiconductor device of claim 9, wherein the first gate electrode and the second gate electrode are formed of the same material.

16. An integrated circuit semiconductor device comprising:
a first region including a first multi-bridge channel transistor including a first active fin protruding from a substrate and extending in a first direction, a first gate dielectric layer extending from a top surface of the first active fin onto a first isolation layer in a second direction perpendicular to the first direction, a plurality of first nano-sheets stacked apart from the first gate dielectric layer, a third gate dielectric layer surrounding the first nano-sheets, first and second barrier metal layers formed on the first gate dielectric layer, on an upper portion of the third gate dielectric layer, and between the first nano-sheets, and extending in the second direction, and a first gate electrode formed on the second barrier metal layer;
a second region formed adjacent to the first region in the second direction, wherein the second region comprises a second multi-bridge channel transistor including a second active fin protruding from the substrate and extending in the first direction, a second gate dielectric layer extending from a top surface of the second active fin onto a second isolation layer in the second direction, a plurality of second nano-sheets stacked apart from the second gate dielectric layer, a fourth gate dielectric layer surrounding the second nano-sheets, a third barrier metal layer formed on the second gate dielectric layer, on an upper portion of the fourth gate dielectric layer, and between the second nano-sheets and extending in the second direction, and a second gate electrode formed on the third barrier metal layer; and
a metal dam positioned at a boundary of the first region and the second region to physically separate the first gate electrode and the second gate electrode in the second direction,
wherein the metal dam, the first gate electrode, and the second gate electrode are electrically connected to each other.

17. The integrated circuit semiconductor device of claim 16, wherein the metal dam is a metal dam pattern, and
wherein sidewalls of the metal dam pattern extending in a direction perpendicular to a surface of the substrate are in contact with the first barrier metal layer and the third barrier metal layer.

18. The integrated circuit semiconductor device of claim 16, wherein the first and second barrier metal layers are thicker than the third barrier metal layer.

19. The integrated circuit semiconductor device of claim 16, wherein the first gate electrode and the second gate electrode have the same width in the first direction.

20. The integrated circuit semiconductor device of claim 16, wherein the first multi-bridge channel transistor comprises a P-type multi-bridge channel transistor, and the second multi-bridge channel transistor comprises an N-type multi-bridge channel transistor.
